(19) United States
(12) Patent Application Publication
(10) Pub. No.: US 2026/0016505 A1
(43) Pub. Date: Jan. 15, 2026

(54) PROBE ASSEMBLY, PROBE SYSTEM, METHOD FOR MAINTAINING ALIGNMENT, AND SEMICONDUCTOR DEVICE TESTED

(71) Applicant: MPI CORPORATION, Zhubei City (TW)

(72) Inventor: Yu-Hsun Hsu, Zhubei City (TW)

(21) Appl. No.: 19/266,569

(22) Filed: Jul. 11, 2025

Related U.S. Application Data
(60) Provisional application No. 63/671,412, filed on Jul. 15, 2024.

(51) Int. Cl. G01R 1/44; G01R 1/04

(52) U.S. Cl. CPC G01R 1/44; G01R 1/0416

(57) ABSTRACT

A probe assembly includes at least one probe, a probe holder, and an adaptor. The probe is configured to include a probe tip and has a first a first length and a first coefficient of thermal expansion. The probe holder is configured to hold the probe, and has a second length and a second coefficient of thermal expansion. The adaptor is configured to attach to the probe holder, and has a third length and a third coefficient of thermal expansion. Furthermore, the first coefficient of thermal expansion is a positive coefficient of thermal expansion, and one of the second coefficient of thermal expansion and the third coefficient of thermal expansion corresponds to either: a material having a negative coefficient of thermal expansion; or a composite structure comprising a positive thermal expansion material and a negative thermal expansion material, arranged such that the overall thermal expansion characteristic is stable.

### CROSS-REFERENCE TO RELATED APPLICATIONS

This application claims priority to U.S. Provisional Applications No. 63/671,412 filed on Jul. 15, 2024, the entire contents of which are incorporated herein by reference.

### BACKGROUND OF THE INVENTION

The present invention relates to a probe assembly, a probe system, and a method for maintaining alignment between a probe tip of the probe assembly and a device under test (DUT). More specifically, the present invention relates to how the probe assembly, the probe system, and the method prevents misalignment errors between the probe tips of the probe assembly and the device under test caused by temperature variations.

For the semiconductor manufacturing industry, it is necessary to equip a probe assembly in wafer probe stations to test the device under test. As the demand for higher testing quality of the device under test currently increases, the alignment accuracy between the probe assembly and the device under test has become increasingly important. In a general testing process, the wafer probe stations may heat or cool the temperature of the probe assembly. However, due to the coefficient of thermal expansion (CTE) of the materials used in conventional probe assembly, the length of the probe assembly changes accordingly when temperature fluctuations occur. That is, the probe assembly expands when heated and contracts when cooled. In precision testing scenarios, this leads to a change in the relative position between the probe tips of the probe assembly and the device under test, and any displacement of the probe tips could result in inaccurate measurements. Some probe assemblies are in parallel mechanical structure relationship have been proposed, in which different components within the probe assembly overlap in the same direction to compensate for the length variation of the probe assembly caused by temperature changes. Nevertheless, these probe assemblies require a complex structure and a large volume. In view of this, a technical problem to be solved is how to provide a probe assembly with a simpler structure and smaller volume while compensating for length variations caused by temperature changes.

### SUMMARY OF THE INVENTION

To overcome at least the aforesaid problem, the present invention provides a probe assembly. The probe assembly may comprise at least one probe, a probe holder, and an adaptor. The probe is configured to include a probe tip, and has a first length and first thermal expansion characteristic, which corresponds to a first coefficient of thermal expansion. The probe holder is configured to hold the probe, and has a second length and a second thermal expansion characteristic, which corresponds to a second coefficient of thermal expansion (CTE). The adaptor is configured to attach to the probe holder, and has a third length and a third thermal expansion characteristic, which corresponds to a third coefficient of thermal expansion. Furthermore, the first coefficient of thermal expansion is a positive coefficient of thermal expansion, and one of the second coefficient of thermal expansion or the third coefficient of thermal expansion corresponds to either: a material having a negative coefficient of thermal expansion; or a composite structure comprising a positive thermal expansion material and a negative thermal expansion material, arranged such that the overall thermal expansion characteristic is stable.

To overcome at least the aforesaid problem, the present invention also provides a probe system for testing a device under test that is formed on a substrate. The probe system may comprise a chuck, a probe assembly, a vision system, a positioning assembly, and a signal processing assembly. The chuck is configured to support the substrate. The probe assembly is as described in the above-mentioned paragraph. The vision system is configured to capture an image of at least a region of the probe system. The positioning assembly is configured to selectively vary a relative orientation between the chuck and the probe tip of the probe. The signal processing assembly is configured to at least one of supply a test signal to the device under test or receive a resultant signal of the test from the device under test.

To overcome at least the aforesaid problem, the present invention also provides a method for maintaining alignment between a probe tip of at least one probe of the probe assembly and a device under test within a probe system, wherein the probe (12) has a first length (L1) and a first thermal expansion characteristic, which corresponds to a first coefficient of thermal expansion. The method may comprise the following steps: providing a probe holder with a second length and a second thermal expansion characteristic, which is configured to hold the probe, wherein the second thermal expansion characteristic corresponds to a second coefficient of thermal expansion; providing an adaptor with a third length and a third thermal expansion characteristic, which is configured to attach to the probe holder, wherein the third thermal expansion characteristic corresponds to a third coefficient of thermal expansion; positioning the probe tip at a desired location relative to the device under test; and counteracting the displacement of the probe tip caused by a temperature changes in the probe system, by one of the second coefficient of thermal expansion (CTE 2) and the third coefficient of thermal expansion (CTE 3) corresponds to either: a material having a negative coefficient of thermal expansion; or a composite structure comprising a positive thermal expansion material and a negative thermal expansion material, arranged such that the overall thermal expansion characteristic is stable.

The present invention further provides a semiconductor device tested by the above-mentioned method.

As described above, in the technology provided by the present invention (at least including the probe assembly, probe system, and the method) for maintaining the alignment of the probe tip of the probe assembly with the device under test, where the probe assembly is composed as a series mechanical structure by connecting multiple components (e.g., a probe holder and an adaptor) with opposing thermal expansion characteristics. The differences in their thermal expansion characteristics of the components allow them to adjust and compensate for length variations caused by temperature changes, thereby ensuring that the probe tip remains in a fixed position relative to the device under test. Accordingly, as disclosed the above-mentioned problems faced by conventional probe assembly can be solved effectively.

The summary of the invention is not intended to limit the present invention, but merely provides basic profile of the present invention. The details of the present invention will be described with various embodiments as presented below.

### BRIEF DESCRIPTION OF DRAWINGS

FIG. 1 illustrates a schematic view of a probe assembly according to some embodiments of the present invention.

FIG. 2 illustrates a schematic view of how an adaptor is used to compensate for the change in the length of a probe assembly according to some embodiments of the present invention.

FIG. 3 illustrates a schematic view of how a probe holder is used to compensate for the change in the length of a probe assembly according to some embodiments of the present invention.

FIG. 4 illustrates a schematic view of how a probe holder is used to compensate for the change in the length of a probe assembly according to some other embodiments of the present invention.

FIG. 5 illustrates a schematic view of how an adaptor is used to compensate for the change in the length of the probe assembly according to some other embodiments of the present invention.

FIG. 6 illustrates a schematic view of a probe system according to some embodiments of the present invention.

FIG. 7 illustrates a flowchart for describing a method for maintaining alignment between a probe tip of the probe assembly and a device under test within a probe system.

### DETAILED DESCRIPTION OF THE INVENTION

The embodiments as disclosed below are not intended to limit the present invention to any specific environment, applications, structures, processes or situations. In the attached drawings, elements which are not directly related to the present invention are omitted from depiction. Dimensions and dimensional relationships within individual elements in the attached drawings are only exemplary examples and are not intended to limit the present invention. Unless stated particularly, same element numerals may correspond to same elements in the following description without inconsistency with the present invention.

The terminology used herein is for the purpose of describing the embodiments only and is not intended to limit the present invention. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first”, “second” and “third” etc., may be used herein to describe various elements, these elements should not be limited by these terms. These terms are merely used to distinguish one element from other elements. Thus, for example, a first element described below could also be termed a second element, without departing from the spirit and scope of the present invention.

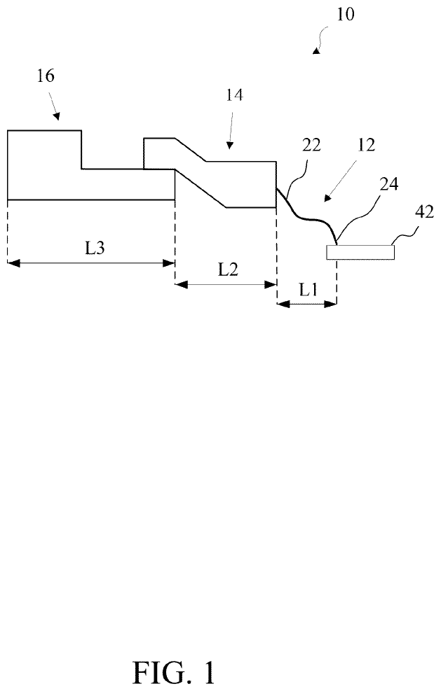

Some embodiments of the present invention relate to a probe assembly (which is referred to as a “probe assembly 10” hereinafter) for a probe system (which is referred to as a “probe system 1” hereinafter). FIG. 1 illustrates, a schematic view of the probe assembly 10 according to some embodiments of the present invention. The contents shown in FIG. 1 are provided only for illustrating embodiments of the present invention and should not be construed as any limitations on the present invention.

As shown in FIG. 1, the probe assembly 10 is composed of multiple components arranged in a series mechanical structure. For example, the probe assembly 10 basically comprises at least one probe 12, a probe holder 14, and an adaptor 16. That is, the probe 12, the probe holder 14, and the adaptor 16 are connected in a series mechanical structure. Specifically, the series mechanical structure refers to an arrangement where multiple components are connected sequentially, such that the movement or adjustment of one component directly impacts the movement or position of the subsequent component in the series. Probe 12 may have any appropriate form and/or structure for testing device under test (DUT) 42. For example, and as schematically illustrated in FIG. 1, Probe 12 may include a probe body 22 and a probe tip (or needle tip) 24 extending from probe body 22 for establishing electrical and/or optical contact and/or communication with the DUT 42. Probe 12 may include any appropriate number of probe tips, such as one probe tip, two probe tips, three probe tips, or more than three probe tips.

In this case, the probe(s) 12 may be the component that interacts with the DUT 42 to perform measurements, and the probe tip 24 that makes physical contact with the DUT 42, wherein the probe(s) 12 may have a first length L1 and a first coefficient of thermal expansion (hereinafter referred to as “CTE 1”). The probe holder 14 may be the component that holds or supports the probe(s) 12, and has a second length L2 and a second thermal expansion characteristic, which corresponds to a second coefficient of thermal expansion (hereinafter referred to as “CTE 2”). The adaptor 16 may attach the probe holder 14 to the rest of the apparatus of the probe system 1. Its role would be to provide a stable and secure connection, ensuring that the entire works of the probe assembly 10 as intended without causing misalignment or instability. In addition, the adaptor 16 may have a third length L3 and a third thermal expansion characteristic, wherein the third thermal expansion characteristic corresponds to a third coefficient of thermal expansion (hereinafter referred to as “CTE 3”).

It is noted that, the probe(s) 12 must meet certain performance of electrical requirements or other specifications, the CTE 1 must be positive (i.e., the first thermal expansion characteristic corresponds to a positive thermal expansion characteristic). That is, the probe(s) 12 expands when heated and contracts when cooled. It is noted that, the number of the probe(s) 12 may be one or more, the following description uses a single probe as an example but is not limited thereto.

Furthermore, one of the CTE 2 or the CTE 3 is smaller than the CTE 1, which causes it does not increase as its temperature increases. In the phrase “causes it not to increase as its temperature increases,” the “it” refers to the length of the two components (either the probe holder 14 or the adaptor 16). Specifically, when either CTE 2 or CTE 3 is smaller than CTE 1, it may indicate that the corresponding thermal expansion characteristic is overall stable, or that it corresponds to a negative thermal expansion characteristic.

In some embodiments, the probe holder 14 or the adaptor 16 may be a composite structure, formed by combining a portion made of a material with a positive coefficient of thermal expansion and a portion made of a material with a negative coefficient of thermal expansion, the structural configuration and proportion of which are designed to yield an overall thermally neutral expansion behavior (that is, the coefficient of thermal expansion close to zero), such that the corresponding second thermal expansion characteristic or third thermal expansion characteristic is overall stable. In some alternative embodiments, the second thermal expansion characteristic and the third thermal expansion characteristic are smaller than the CTE 1.

More specifically, although the probe 12 exhibits a positive thermal expansion characteristic, its physical size is typically small. As a result, changes in the first length L1 due to temperature variations are minimal. Thus, it is primarily necessary to ensure that the total variation of the second length L2 and the third length L3 is controlled in order to maintain the relative position of the probe 24.

In this case, a first length change value is equals to the product of the CTE 1, the first length L1 that corresponds to the CTE 1, and a temperature difference; a second length change value is equals to the product of the CTE 2, the second length L2 that corresponds to the CTE 2, and the temperature difference; a third length change value is equals to the product of the CTE 3, the third length L2 that corresponds to the CTE 3, and the temperature difference. Under this circumstance, the sum of the first length change value, the second length change value, and third length change value is approximately zero. Specifically, due to the differences in the thermal expansion characteristics of the probe 12, the probe holder 14 and the adaptor 16, the total value of the length change will be nearly zero when the temperature changes (e.g., from 25° C. to 125° C.), ensuring that the probe tip remains in a fixed position relative to the device under test.

In addition, the following equation further describes the relationship between the length change values of these components, the thermal expansion coefficients, and the temperature difference. That is, “ΔXc=Xc*ΔT*αc”. where, “ΔXc” represents the length change values of the component c (e.g., the probe 12, the probe holder 14, and the adaptor 16), “Xc” represents the length of the component c, “ΔT” represents the temperature difference, and “ac” represents the coefficient of thermal expansion of the component c (e.g., CTE 1, CTE 2, and CTE 3).

In some embodiment, among the components of the probe assembly 10, one component other the probe 12 (i.e., either the probe holder 14 or the adaptor 16) may be made entirely from a material having a negative coefficient of thermal expansion, while the other component may be made from a material having a positive coefficient of thermal expansion. That is, the second thermal expansion characteristic and the third thermal expansion characteristic are inverse. Specifically, one of the two components (either the probe holder 14 or the adaptor 16) has a negative thermal expansion characteristic, meaning that as the temperature of the material increases, its length decreases or contracts, rather than expanding as typical materials would. This negative thermal expansion helps compensate for temperature-induced length variations in the probe assembly 10, aiding in maintaining proper alignment between the probe tip 24 and the DUT 42.

Specifically, the second thermal expansion characteristic of the probe holder 14 is a positive thermal expansion characteristic (i.e., the CTE 2 corresponding to the second thermal expansion characteristic is positive), which means that the second length L2 of the probe holder 14 expands when heated and contracts when cooled. In contrast, the third thermal expansion characteristic of the adaptor 16 is a negative thermal expansion characteristic (i.e., the CTE 3 is negative coefficient of thermal expansion), which means that the third length L3 of the adapter 16 expands when cooled and contracts when heated. In this setup, when the temperature of the probe system 1 changes, the length variation of the probe assembly 10 can be compensated through different thermal expansion characteristics of the components within the probe assembly 10.

In more detail, most metallic materials in the world have positive thermal expansion characteristics, meaning that their size (or length in a certain direction) naturally increases with increasing temperature. However, there are some specific metallic materials that have negative thermal expansion characteristics, such as “ALLVAR Alloys”, which shrink in size (or length in a certain direction) as the temperature increases.

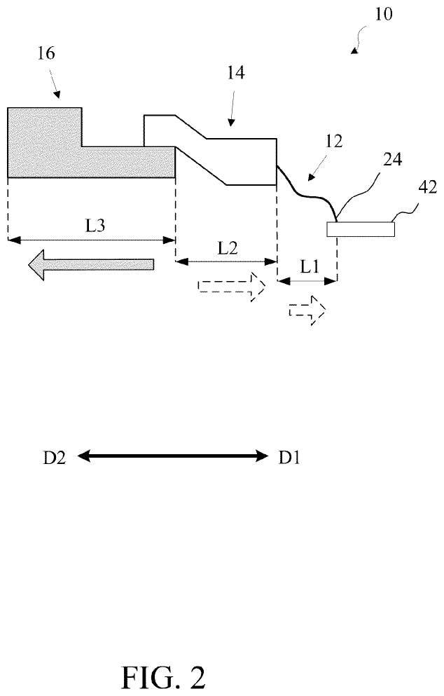

FIG. 2 illustrates a schematic view of how the adaptor 16 is used to compensate for the change in the length of the probe assembly 10 according to some embodiments of the present invention. The contents shown in FIG. 2 is only for exemplifying the embodiment of the present invention, and are not intended to limit the scope claimed in the present invention.

As shown in FIG. 2, for example, when the temperature of the probe system 1 increases, since the CTE 1 of the probe 12 and the CTE 2 of the probe holder 14 correspond to positive coefficient of thermal expansion, the probe 12 and the probe holder 14 expand, causing their length (i.e., the first length L1 and the second length L2) to increase in a first direction D1 (see dashed arrow), the probe tip 24 may be displaced forward by several tens of micrometers (μm). Meanwhile, since the CTE 3 of the adaptor 16 corresponds to negative coefficient of thermal expansion, the adaptor 16 contracts, causing the third length L3 to increase in a second direction D2 (see gray arrow), thereby pulling the probe 12 and the probe holder 14 in the opposite direction along the second direction D2. Therefore, the adaptor 16 can be referred to as a compensation component (shown in gray), and the adaptor 16 which has negative thermal expansion characteristic can counteract for the length changes of the probe 12 and the probe holder 14 which have positive coefficient of thermal expansion, ensuring that the probe tip 24 remains in a fixed position relative to the DUT 42.

More specifically, an absolute value of the product of the CTE 3 and the third length L3 is a compensation component deviation value. Next, the sum of the absolute value of the product of the CTE 1 and the first length L1, and the absolute value of the product of the CTE 2 and the second length L2 is a component deviation value. In this case, the compensation component deviation value may be equal to, at least substantially equal to, and/or equivalent to the component deviation value. Stated differently, the compensation component deviation value and the component deviation value are considered “at least substantially equal” when the deviation between them is less than a threshold deviation value, which can be defined by a specific threshold (for example, 0.5%, 1%, 2%, or any other suitable threshold). In other words, the length variation of the compensation component (i.e., the adaptor 16) may be equal to, at least substantially equal to, and/or equivalent to the length variation of the other components (i.e., the probe 12 and probe holder 14) when the difference between them is less than the threshold deviation value.

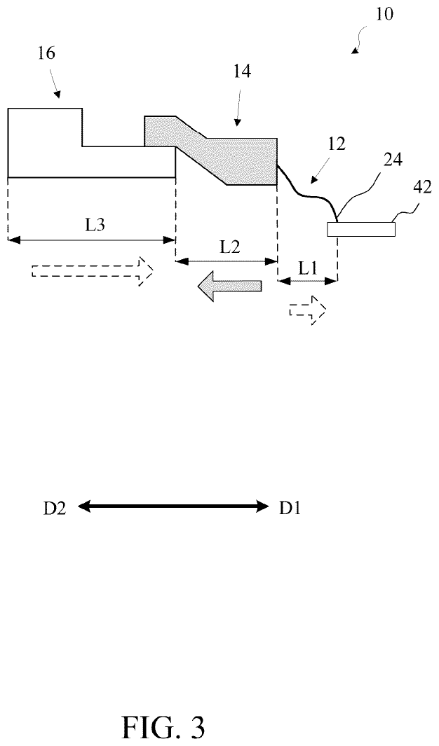

FIG. 3 illustrates a schematic view of how the probe holder 14 is used to compensate for the change in the length of the probe assembly 10 according to some embodiments of the present invention. The contents shown in FIG. 3 is only for exemplifying the embodiment of the present invention, and are not intended to limit the scope claimed in the present invention.

In some embodiments, as shown in FIG. 3, the second thermal expansion characteristic of the probe holder 14 is the negative thermal expansion characteristic (i.e., the CTE 2 is negative coefficient of thermal expansion), which means that the second length L2 of the probe holder 14 expands when cooled and contracts when heated. In contrast, the third thermal expansion characteristic of the adaptor 16 is the positive thermal expansion characteristic (i.e., the CTE 3 corresponding to the third thermal expansion characteristic is positive), which means that the third length L3 of the adapter 16 expands when heated and contracts when cooled.

For example, when the temperature of the probe system 1 increases, since the CTE 1 of the probe 12 and the CTE 3 of the adaptor 16 correspond to positive coefficient of thermal expansion, the probe 12 and the adaptor 16 expand, causing their length (i.e., the first length L1 and the third length L3) to increase in the first direction D1 (see dashed arrow). Moreover, since the CTE 2 of the probe holder 14 corresponds to negative coefficient of thermal expansion, the probe holder 14 contracts, causing the second length L2 to increase in the second direction D2 (see gray arrow), thereby pulling the probe 12 and the adaptor 16 in the opposite direction along the second direction D2. Therefore, the probe holder 14 can be referred to as a compensation component (shown in gray), and the probe holder 14 which has negative thermal expansion characteristic can counteract for the length changes of the probe 12 and the adaptor 16 which have positive coefficient of thermal expansion, ensuring that the probe tip 24 remains in a fixed position relative to the DUT 42.

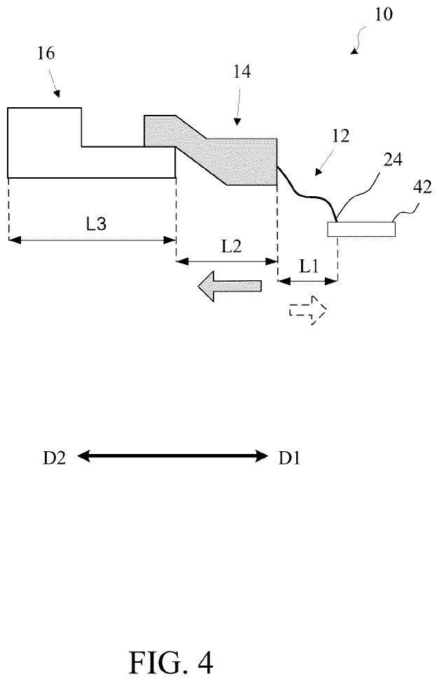

FIG. 4 illustrates a schematic view of how the probe holder 14 is used to compensate for the change in the length of the probe assembly 10 according to some other embodiments of the present invention. The contents shown in FIG. 4 is only for exemplifying the embodiment of the present invention, and are not intended to limit the scope claimed in the present invention.

In some embodiments, as shown in FIG. 4, the second thermal expansion characteristic of the probe holder 14 is the negative thermal expansion characteristic (i.e., the CTE 2 is negative coefficient of thermal expansion), which means that the second length L2 of the probe holder 14 expands when cooled and contracts when heated. However, the CTE 1 of the probe 12 corresponding to positive thermal expansion characteristics, and the CTE 3 of the adaptor 16 is smaller than the CTE 1, which means that the third length L3 of the adaptor 16 remains nearly unchanged, or at least substantially unchanged during heating and cooling.

For example, when the temperature of the probe system 1 increases, since the CTE 1 corresponds to positive coefficient of thermal expansion, the probe 12 expand, which causes the first length L1 to increase in the first direction D1 (see dashed arrow). Additionally, the third length L3 of the adaptor 16 remains nearly unchanged, or at least substantially unchanged as the temperature increases. Moreover, since the CTE 2 corresponds to negative coefficient of thermal expansion, causing the second length L2 to increase in the second direction D2 (see gray arrow), thereby pulling the probe 12 in the opposite direction along the second direction D2. Therefore, the probe holder 14 can be referred to as a compensation component (shown in gray), and the probe holder 14 with negative thermal expansion characteristic can counteract for the length changes of the probe 12, which has positive coefficient of thermal expansion, ensuring that the probe tip 24 remains in a fixed position relative to the DUT 42.

In some alternative embodiments, the probe holder 14 or the adaptor 16 may be made of a thermally stable material with the CTE 2 or CTE 3 close to zero. Furthermore, the thermally stable material used to make the probe holder 14 or the adaptor 16 can be Nobinite, Invar, or ceramic materials, which are materials with a low, or extremely low CTE. For example, some nickel-iron alloys provide a CTE of less than about 1.5 ppm per degree Celsius.

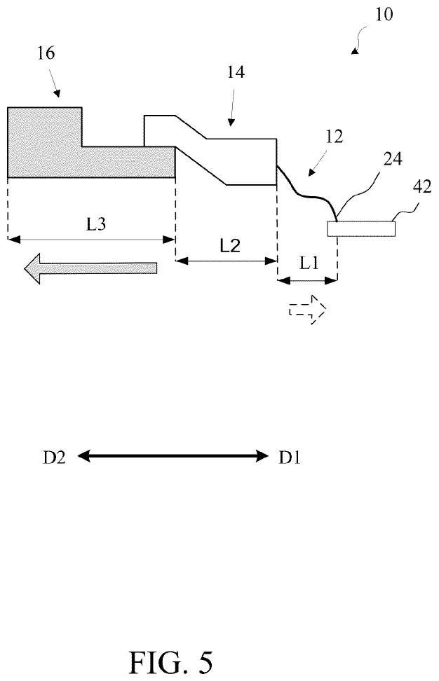

FIG. 5 illustrates a schematic view of how the adaptor 16 is used to compensate for the change in the length of the probe assembly 10 according to some other embodiments of the present invention. The contents shown in FIG. 5 is only for exemplifying the embodiment of the present invention, and are not intended to limit the scope claimed in the present invention.

In some embodiments, as shown in FIG. 5, the third thermal expansion characteristic of the adaptor 16 is the negative thermal expansion characteristic (i.e., the CTE 3 is negative coefficient of thermal expansion), which means that the third length L3 of the adaptor 16 expands when cooled and contracts when heated. However, the CTE 1 of the probe 12 corresponding to positive thermal expansion characteristic, and the CTE 2 of the probe holder 14 is smaller than the CTE 1, which means that the second length L2 of the probe holder 14 remains nearly unchanged, or at least substantially unchanged during heating and cooling.

For example, when the temperature of the probe system 1 increases, since the CTE 1 corresponds to positive coefficient of thermal expansion, the probe 12 expand, which causes the first length L1 to increase in the first direction D1 (see dashed arrow). Additionally, the second length L2 to remain nearly unchanged, or at least substantially unchanged as the temperature increases. Moreover, since the CTE 3 corresponds to negative coefficient of thermal expansion, causing the third length L3 to increase in the second direction D2 (see gray arrow), thereby pulling the probe 12 and the probe holder 14 in the opposite direction along the second direction D2. Therefore, the adaptor 16 can be referred to as a compensation component (shown in gray), and the adaptor 16 with negative thermal expansion characteristic can counteract for the length changes of the probe 12, which has positive coefficient of thermal expansion, ensuring that the probe tip 24 remains in a fixed position relative to the DUT 42.

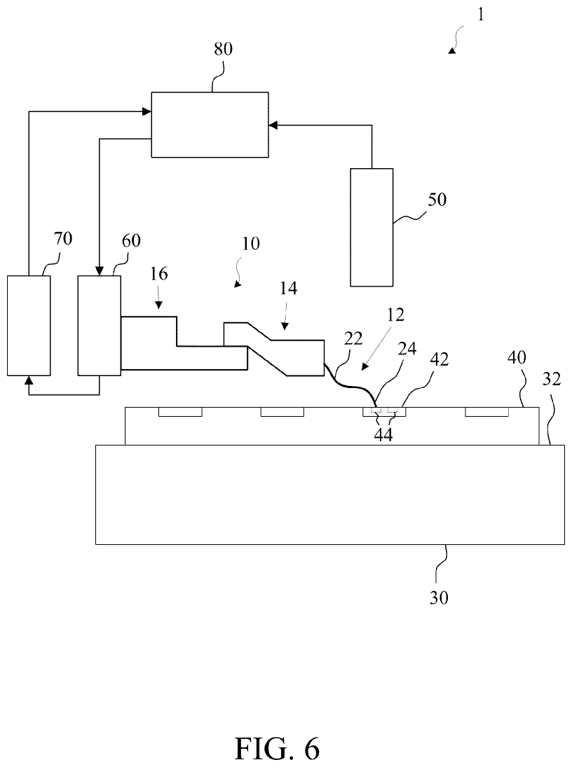

Some embodiments of the present invention relate to the probe system 1, whose schematic view is depicted in FIG. 6. The probe system 1 using the probe assembly 10 can also be used for testing the DUT 42 that is formed on a substrate 40. More specifically, the probe system 1 may include a chuck 30, the probe assembly 10, a vision system 50, a positioning assembly 60, a signal processing assembly 70, and a controller 80.

Specifically, the chuck 30 is configured to support the substrate 40, that is, the substrate 40 is placed on a chuck support surface 32 of the chuck 30. The probe assembly 10 can be implemented in all of the above-mentioned embodiments. The controller 80 may be configured to electrically connected to the vision system 50, the signal processing assembly 70, and a controller 80 and control them through a control signal. The vision system 50 may be an optical imaging device, which is configured to capture an image of at least a region of the probe system 1 and transmit the image to the controller 80. The positioning assembly 60 may be an electrically actuated positioning assembly, which is configured to selectively vary a relative orientation between the probe tip 24 of the at least one probe and the chuck 30. The signal processing assembly 70 may be configured to electrically connected to the probe assembly 10 and make contact with a plurality of contact pads 44 of the DUT 42 through the probe tip 24, and is configured to at least one of supply a test signal to the DUT 42 or receive a resultant signal of the test from the DUT 42.

In this case, the signal processing assembly 70, when present, may be adapted, configured, designed, and/or constructed to provide a test signal to the DUT 42 via a probe tip 24 of probe assembly 10 and/or to receive a resultant signal from the DUT 42 via the probe tip 24. Examples of the test signal include an electric test signal, an optical test signal, and/or an electromagnetic test signal. Examples of the resultant signal include an electric resultant signal, an optical resultant signal, and/or an electromagnetic resultant signal. Examples of signal processing assembly 70 include a signal generator, an electric signal generator, an optical signal generator, a signal transmitter, an electric signal transmitter, an optical signal transmitter, a signal receiver, an electric signal receiver, an optical signal receiver, a signal analyzer, an electric signal analyzer, and/or an optical signal analyzer.

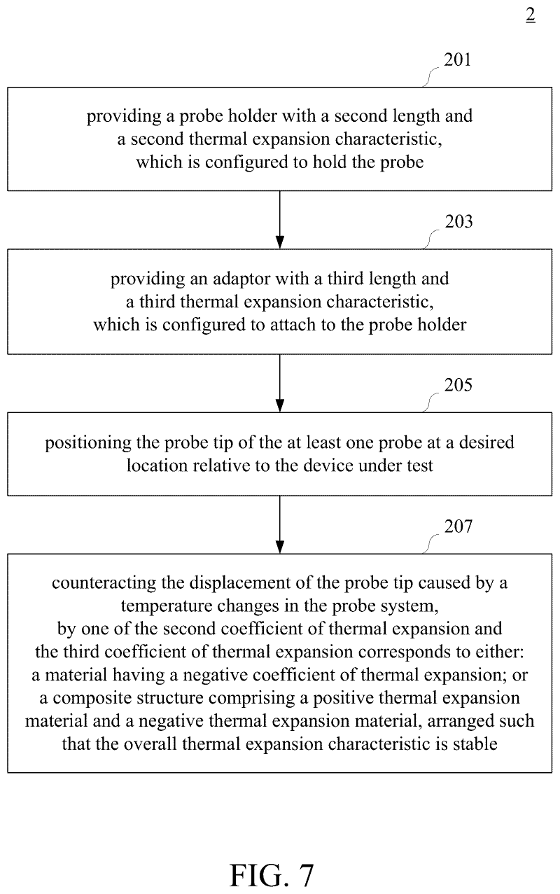

Some embodiments of the present invention relate to a method for maintaining alignment between a probe tip 24 of the probe assembly 10 and the DUT 42 within a probe system 1 (which is referred to as a “method 2” hereinafter), wherein the probe (12) has a first length (L1) and a first thermal expansion characteristic, which corresponds to a positive thermal expansion characteristic. FIG. 7 illustrates a flowchart for describing the method 2 according to some embodiments of the present invention, but the contents shown in FIG. 7 are only for exemplifying the embodiment of the present invention, and are not intended to limit the scope claimed in the present invention.

As shown in FIG. 7, the method 2 may comprise the following steps: providing a probe holder with second length and a second thermal expansion characteristic, which is configured to hold the probe (marked as step “201”), wherein the second thermal expansion characteristic corresponds to a second coefficient of thermal expansion; providing an adaptor with a third length and a third thermal expansion characteristic, which is configured to attach to the probe holder (marked as step “203”), wherein the third thermal expansion characteristic corresponds to a third coefficient of thermal expansion; positioning the probe tip at a desired location relative to the device under test (marked as step “205”); and counteracting the displacement of the probe tip caused by a temperature changes in the probe system, by one of the second coefficient of thermal expansion and the third coefficient of thermal expansion corresponds to either: a material having a negative coefficient of thermal expansion; or a composite structure comprising a positive thermal expansion material and a negative thermal expansion material, arranged such that the overall thermal expansion characteristic is stable (marked as step “207”).

In some embodiments of the method 2, wherein a first length change value is equals to the product of the first coefficient of thermal expansion (CTE 1), the first length (L1) that corresponds to the first coefficient of thermal expansion (CTE 1), and a temperature difference; second length change value is equals to the product of the second coefficient of thermal expansion (CTE 2), the second length (L2) that corresponds to the second coefficient of thermal expansion (CTE 2), and the temperature difference; and a third length change value is equals to the product of the third coefficient of thermal expansion (CTE 3), the third length (L3) that corresponds to the third coefficient of thermal expansion (CTE 3), and the temperature difference; wherein the sum of the first length change value, the second length change value, and third length change value is approximately zero.

In some embodiments of the method 2, wherein one of the second coefficient of thermal expansion or the third coefficient of thermal expansion is the negative thermal expansion characteristic; and the second thermal expansion characteristic and the third thermal expansion characteristic are inverse.

In some embodiments of the method 2, wherein a compensation component deviation value is defined as an absolute value of the product of either the second coefficient of thermal expansion (CTE 2) or the third coefficient of thermal expansion (CTE 3), which is the negative coefficient of thermal expansion, its corresponding second length (L2) or third length (L3), and a temperature difference; and a component deviation value is defined as the sum of: the absolute value of the product of the first coefficient of thermal expansion (CTE 1), the first length (L1), and the temperature difference; and the absolute value of the product of the second coefficient of thermal expansion (CTE 2) or the third coefficient of thermal expansion (CTE 3), its corresponding second length (L2) or third length (L3), and the temperature difference; the compensation component deviation value is at least substantially equal to the component deviation value.

In some embodiments of the method 2, wherein the second coefficient of thermal expansion is the negative coefficient of thermal expansion; and the third coefficient of thermal expansion is smaller than the first coefficient of thermal expansion.

In some embodiments of the method 2, wherein the adaptor is made of a thermally stable material with the third coefficient of thermal expansion close to zero.

In some embodiments of the method 2, wherein the third coefficient of thermal expansion is the negative thermal expansion characteristic; and the second coefficient of thermal expansion is smaller than the first coefficient of thermal expansion.

In some embodiments of the method 2, wherein the second coefficient of thermal expansion close to zero.

In some embodiments of the method 2, wherein the thermally stable material is Nobinite, Invar, or ceramic materials.

In some embodiments of the method 2, wherein the probe, the probe holder and the adaptor are connected in a series mechanical structure.

Each embodiment of the method 2 substantially corresponds to at least one embodiment of the probe assembly 10. Therefore, all the corresponding embodiments of the method 2 can be fully appreciated by those of ordinary skill in the art simply with reference to the above description of the probe assembly 10, even though not all the embodiments of the method 2 are described in detail above.

Some embodiments of the present invention relate to a semiconductor device tested by the method 2.

The above embodiments are only examples for illustrating the present invention, and are not intended to limit the scope claimed in the present invention. Any other embodiments produced by modifying, changing, adjusting and integrating the above-mentioned embodiments shall all be included in the scope claimed in the present invention as long as they are not difficult for those of ordinary skill in the art to contemplate. The scope claimed in the present invention shall be governed by the claims.

As used herein, “at least substantially,” when modifying a degree or relationship, may include not only the recited “substantial” degree or relationship, but also the full extent of the recited degree or relationship. For example, a first length that is at least substantially as long as a second length includes first lengths that are within 90% of the second length and also includes first lengths that are as long as the second length.

1. A probe assembly (10) for a probe system (1), comprising:
at least one probe (12), being configured to include a probe tip (24), and has a first length (L1) and a first thermal expansion characteristic, which corresponds to a first coefficient of thermal expansion (CTE 1);
a probe holder (14), being configured to hold the probe (12), and has a second length (L2) and a second thermal expansion characteristic, which corresponds to a second coefficient of thermal expansion (CTE 2); and
an adaptor (16), being configured to attach to the probe holder (14), and has a third length (L3) and a third thermal expansion characteristic, which corresponds to a third coefficient of thermal expansion (CTE 3);
wherein the first coefficient of thermal expansion (CTE 1) is a positive coefficient of thermal expansion, and one of the second coefficient of thermal expansion (CTE 2) and the third coefficient of thermal expansion (CTE 3) corresponds to either:
a material having a negative coefficient of thermal expansion; or
a composite structure comprising a positive thermal expansion material and a negative thermal expansion material, arranged such that the overall thermal expansion characteristic is stable.

2. The probe assembly (10) of claim 1, wherein:
a first length change value is equals to the product of the first coefficient of thermal expansion (CTE 1), the first length (L1) that corresponds to the first coefficient of thermal expansion (CTE 1), and a temperature difference;
a second length change value is equals to the product of the second coefficient of thermal expansion (CTE 2), the second length (L2) that corresponds to the second coefficient of thermal expansion (CTE 2), and the temperature difference; and
a third length change value is equals to the product of the third coefficient of thermal expansion (CTE 3), the third length (L3) that corresponds to the third coefficient of thermal expansion (CTE 3), and the temperature difference;
wherein the sum of the first length change value, the second length change value, and third length change value is approximately zero.

3. The probe assembly (10) of claim 1, wherein:
one of the second coefficient of thermal expansion (CTE 2) or the third coefficient of thermal expansion (CTE 3) is the negative coefficient of thermal expansion; and
the second thermal expansion characteristic and the third thermal expansion characteristic are inverse.

4. The probe assembly (10) of claim 3, wherein:
a compensation component deviation value is defined as an absolute value of the product of either the second coefficient of thermal expansion (CTE 2) or the third coefficient of thermal expansion (CTE 3), which is the negative coefficient of thermal expansion, its corresponding second length (L2) or third length (L3), and a temperature difference; and
a component deviation value is defined as the sum of:
the absolute value of the product of the first coefficient of thermal expansion (CTE 1), the first length (L1), and the temperature difference; and
the absolute value of the product of the second coefficient of thermal expansion (CTE 2) or the third coefficient of thermal expansion (CTE 3), its corresponding second length (L2) or third length (L3), and the temperature difference;
the compensation component deviation value is at least substantially equal to the component deviation value.

5. The probe assembly (10) of claim 1, wherein:
the second coefficient of thermal expansion (CTE 2) is the negative coefficient of thermal expansion; and
the third coefficient of thermal expansion (CTE 3) is smaller than the first coefficient of thermal expansion (CTE 1).

6. The probe assembly (10) of claim 5, wherein:
the adaptor (16) is made of a thermally stable material with the third coefficient of thermal expansion (CTE 3) close to zero.

7. The probe assembly (10) of claim 1, wherein:
the third coefficient of thermal expansion (CTE 3) is the negative coefficient of thermal expansion; and
the second coefficient of thermal expansion (CTE 2) is smaller than a first coefficient of thermal expansion (CTE 1).

8. The probe assembly (10) of claim 7, wherein:
the probe holder (14) is made of a thermally stable material with the second coefficient of thermal expansion (CTE 2) close to zero.

9. The probe assembly (10) of claim 1, wherein the probe (12), the probe holder (14) and the adaptor (16) are connected in a series mechanical structure.

10. A probe system (1) for testing a device under test that is formed on a substrate (40), comprising:
a chuck (30), being configured to support the substrate (40);
a probe assembly (10) of the claim 1;
a vision system (50), being configured to capture an image of at least a region of the probe system (1);
a positioning assembly (60), being configured to selectively vary a relative orientation between the chuck (30) and the probe tip (24) of the probe (12); and
a signal processing assembly (70), being configured to at least one of supply a test signal to the device under test or receive a resultant signal of the test from the device under test.

11. A method (2) for maintaining alignment between a probe tip (24) of at least one probe (12) of a probe assembly (10) and a device under test within a probe system (1), wherein the probe (12) has a first length (L1) and a first thermal expansion characteristic, which corresponds to a first coefficient of thermal expansion (CTE 1), comprising:
providing a probe holder (14) with a second length (L2) and a second thermal expansion characteristic, which is configured to hold the probe (12), wherein the second thermal expansion characteristic corresponds to a second coefficient of thermal expansion (CTE 2);
providing an adaptor (16) with a third length (L3) and a third thermal expansion characteristic, which is configured to attach to the probe holder (14), wherein the third thermal expansion characteristic corresponds to a third coefficient of thermal expansion (CTE 3);
positioning the probe tip (24) at a desired location relative to the device under test; and
counteracting the displacement of the probe tip (24) caused by temperature changes in the probe system (1), by one of the second coefficient of thermal expansion (CTE 2) and the third coefficient of thermal expansion (CTE 3) corresponds to either:
a material having a negative coefficient of thermal expansion; or
a composite structure comprising a positive thermal expansion material and a negative thermal expansion material, arranged such that the overall thermal expansion characteristic is stable.

12. The method (2) of claim 11, wherein:
a first length change value is equals to the product of the first coefficient of thermal expansion (CTE 1), the first length (L1) that corresponds to the first coefficient of thermal expansion (CTE 1), and a temperature difference;
a second length change value is equals to the product of the second coefficient of thermal expansion (CTE 2), the second length (L2) that corresponds to the second coefficient of thermal expansion (CTE 2), and the temperature difference; and
a third length change value is equals to the product of the third coefficient of thermal expansion (CTE 3), the third length (L3) that corresponds to the third coefficient of thermal expansion (CTE 3), and the temperature difference;
wherein the sum of the first length change value, the second length change value, and third length change value is approximately zero.

13. The method (2) of claim 11, wherein:
one of the second coefficient of thermal expansion (CTE 2) or the third coefficient of thermal expansion (CTE 3) is the negative coefficient of thermal expansion; and
the second thermal expansion characteristic and the third thermal expansion characteristic are inverse.

14. The method (2) of claim 13, wherein:
a compensation component deviation value is defined as an absolute value of the product of either the second coefficient of thermal expansion (CTE 2) or the third coefficient of thermal expansion (CTE 3), which is the negative coefficient of thermal expansion, its corresponding second length (L2) or third length (L3), and a temperature difference; and
a component deviation value is defined as the sum of:
the absolute value of the product of the first coefficient of thermal expansion (CTE 1), the first length (L1), and the temperature difference; and
the absolute value of the product of the second coefficient of thermal expansion (CTE 2) or the third coefficient of thermal expansion (CTE 3), its corresponding second length (L2) or third length (L3), and the temperature difference;
the compensation component deviation value is at least substantially equal to the component deviation value.

15. The method (2) of claim 11, wherein:
the second coefficient of thermal expansion (CTE 2) is the negative coefficient of thermal expansion; and
the third coefficient of thermal expansion (CTE 3) is smaller than the first coefficient of thermal expansion (CTE 1).

16. The method (2) of claim 15, wherein:
the adaptor (16) is made of a thermally stable material with the third coefficient of thermal expansion (CTE 3) close to zero.

17. The method (2) of claim 11, wherein:
the third coefficient of thermal expansion (CTE 3) is the negative coefficient of thermal expansion; and
the second coefficient of thermal expansion (CTE 2) is smaller than the first coefficient of thermal expansion (CTE 1).

18. The method (2) of claim 17, wherein:
the probe holder (14) is made of a thermally stable material with the second coefficient of thermal expansion (CTE 2) close to zero.

19. The method (2) of claim 11, wherein the probe (12), the probe holder (14) and the adaptor (16) are connected in a series mechanical structure.

20. A semiconductor device tested by the method (2) of claim 11.
